(19) United States
(12) Patent Application Publication
(10) Pub. No.: US 2010/0297786 A1
(43) Pub. Date: Nov. 25, 2010

(54) Method for Manufacturing Compound Semiconductor and Apparatus for Manufacturing the Same

(75) Inventors: Kazutaka Terashima, Fujisawa-Shi (JP); Suzuka Nishimura, Fujisawa-Shi (JP); Hirosi Nagayoshi, Fujisawa-Shi (JP); Hiroshi Kawamura, Tokyo (JP); Kazuhiro Haga, Tokyo (JP)

Correspondence Address: BIRCH STEWART KOLASCH & BIRCH, PO BOX 747, FALLS CHURCH, VA, 22040-0747, US

(73) Assignees: Nitto Koki Kabushiki Kaisha, Tokyo (JP); Yugen Kaisha Solates Labo, Fujisawa-Shi (JP)

(21) Appl. No.: 12/225,420

(22) PCT Filed: Mar. 20, 2007
(86) PCT No.: PCT/JP2007/056508

§ 371 Date: Jan. 10, 2009

(30) Foreign Application Priority Data
Mar. 22, 2006 (JP) 2006-78915

(51) Int. Cl. H01L 21/20; B05C 13/02; H01L 21/66

(52) U.S. Cl. 438/16; 118/500; 438/478; 257/E21.09; 257/E21.529

(57) ABSTRACT

The present invention provides a method for manufacturing a compound semiconductor, which can improve a quality of each of thin film layers constituting a laminate structure.

Each of first and second thin film layers is formed by growing a crystal of each thin film layer one over another on a silicon substrate 2 in first and second vapor deposition chambers 6a and 6b for exclusive use, corresponding to the respective thin film layers. As this crystal growth is carried out under conditions under which nothing other than raw gas materials used therein or those derived therefrom, such as stuck materials, precipitates, etc., exists in the first and second vapor deposition chambers 6a and 6b, a decrease in quality of the second thin film layer can be prevented because an unexpected reaction between the raw gas materials used for the first and second thin film layers, etc. can be suppressed. Moreover, a conveyor space 35 extending between the first vapor deposition chamber 6a and the second vapor deposition chamber 6b, in which the silicon substrate 2 is conveyed, is disposed under an atmosphere of nitrogen gas or in a state of vacuum for suppressing oxidation of the thin film layer, thereby suppressing the oxidation of the first thin film layer constituting the outermost layer of the laminated thin film layers to form oxides.

### TECHNICAL FIELD

The present invention relates to a method for manufacturing a compound semiconductor and an apparatus for manufacturing the same.

### BACKGROUND TECHNOLOGY

A method for manufacturing a compound semiconductor using gas epitaxial growth techniques is disclosed in Japanese Patent Application Publication No. 2005-167,169. This method proposed by this prior art technology uses a manufacturing device composed of one raw gas supply system, two vapor deposition chambers, and one vacuum ventilation system, in which the raw gas supply system and the vacuum ventilation system are used by shifting the vapor deposition chambers. In this system, the raw gas supply system and the vacuum ventilation system are used in common to each of the vapor deposition chambers, and one of the vapor deposition chambers can be used for growing a crystal of a thin film layer during a period of time during which the other vapor deposition chamber is not operated for growing a crystal of a thin film layer, i.e., it is engaged in an operation other than the growing step. This allows a compact device as a whole and improvements in productivity.

A compound semiconductor is such that plural thin films are laminated in a form of a layer on a crystal substrate, for example, as described in Japanese Patent No. 3,372,483. In the method for manufacturing this compound semiconductor, different kinds of raw material gases are supplied to a vapor deposition chamber corresponding to the respective thin film layers to be formed in order to grow a crystal and form a thin film layer one on another on the basis of gas epitaxial growth techniques. As the different kinds of raw material gases are used for forming the thin film layers in this method, a vapor deposition chamber has to be cleaned by ventilating the remaining materials such as residual gases and so on from the vapor deposition chamber and drawn vacuum whenever the formation of each thin film layer has been completed.

Even if vacuum has been drawn from the vapor deposition chamber whenever the formation of each thin film layer has been finished, there may still exist the possibility that remaining materials such as stuck materials, precipitates and so on are left non-removed therefrom and they may react with raw material gases or the like used for the formation of the next thin film layer in an unexpected way, resulting in a decrease of a quality of the thin film layer formed. At this end, improvements in heightening a quality of the thin film layer have the limit in itself even if the ventilation of the vapor deposition chambers into a vacuum would have been carried out at each time whenever the formation of each of the thin film layers has been completed.

With the above situation taken into consideration, the present invention has been completed, and the first object of the present invention is to provide a method for manufacturing a compound semiconductor that can improve a quality of each thin film layer constituting a laminated structure.

The present invention has a second object to provide an apparatus for manufacturing a compound semiconductor in order to carry out the method for manufacturing the compound semiconductor as the above first object of the present invention.

### DISCLOSURE OF INVENTION

In order to achieve the first object, the present invention provides a method for manufacturing a compound semiconductor (corresponding to the invention as described in claim 1), which involves manufacturing the compound semiconductor with plural thin film layers laminated on a crystal substrate using different kinds of gases; and which comprises:

growing a crystal corresponding to the respective thin film layer and forming it in plural thin film layers one on another in a laminated form on the crystal substrate; and

conveying said crystal substrate through a conveyor space from one vapor deposition chamber to another vapor deposition chamber under an oxidation-control atmosphere under which oxidation of said thin film layer is suppressed. The preferred embodiments of the above aspect of the invention as described in claim 1 are described in claims 2 to 9.

In order to achieve the first object as described above, the present invention provides a method for manufacturing the compound semiconductor to be laminated on the crystal substrate (as described in claim 10), which involves laminating plural thin film layers on the crystal substrate using different kinds of gases and which comprises:

growing a crystal of each thin film layer one on another on the crystal substrate in the plural vapor deposition chambers corresponding to the respective thin film layer to form the thin film layers on the crystal substrate; and

ventilating remaining gases from each of the vapor deposition chambers using a discrete and individual ventilation system.

In order to achieve the second object, the present invention provides an apparatus of manufacturing a compound semiconductor with plural thin film layers laminated on the crystal substrate (as described in claim 11), which comprises:

plural vapor deposition chambers each for growing a crystal of an individual thin film layer on the crystal substrate; and

a conveyor chamber in communication with each of the vapor deposition chambers to ensure a conveyor space for conveying the crystal substrate,

in which the conveyor chamber is set so as to become in an oxidation controlling atmosphere at least upon the conveyance of the crystal substrate. The preferred embodiments of the above aspect of the present invention as described in claim 11 are described in claims 12 et seq.

According to the invention as described in claim 1, it can be noted that, as each of the thin film layers is formed in each of the plural vapor deposition chambers corresponding to the respective thin film layers by growing the corresponding crystal of the thin film on the crystal substrate, there exists nothing other than the raw gases material used in the vapor deposition chambers and materials originating therefrom, such as stuck materials, precipitates and so on. Therefore, there is no possibility that a quality of the resulting thin film layers be decreased due to an unexpected reaction of those materials with other raw gas materials for the next thin film layer. As a consequence, the quality of each of the thin film layers constituting a laminate structure can be improved to a remarkable extent.

Moreover, in this case, the plural vapor deposition chambers are disposed in accordance with the thin film layers so that it becomes needed to convey the crystal substrate from one vapor deposition chamber to the adjacent vapor deposition chamber. Upon conveying the crystal substrate from one vapor deposition chamber to another, the conveyor space is kept under an atmosphere suppressing oxidation of the thin film layer. This can prevent the outermost thin film layer from oxidation during the conveyance of the crystal substrate, thereby causing no occurrence of crystal defects such as dislocation due to the presence of oxides at an interface between the thin film layers. Therefore, this method is advantageous and preferred from the point of view of the suppression of causing crystal defects, too.

In the invention as described in claim 2, the oxidation controlling atmosphere is set to be an atmosphere which is created by an inert gas. By creating the oxidation controlling atmosphere by an inert gas, the oxidation controlling atmosphere (i.e., the inert gas atmosphere) can suppress the formation of oxides on the outermost thin film layer during the conveyance of the crystal substrate.

The invention as described in claim 3 is composed in such a manner that the inert gas atmosphere is advantageously created by nitrogen gas which is readily available; the inert gas atmosphere created by nitrogen gas can suppress the formation of oxides on the outermost layer of the thin film during conveying the crystal substrate.

According to the invention as described in claim 4, the oxidation controlling atmosphere is also created by a vacuum so that the oxidation controlling atmosphere created by the state of a vacuum can suppress the formation of oxides on the outermost layer of the thin film during conveying the crystal substrate.

The present invention in another aspect of the present invention as described in claim 5 relates to an apparatus for manufacturing the compound semiconductor, which comprises a vapor deposition chamber consisting of plural vapor deposition chambers, e.g., a first vapor deposition chamber and a second vapor deposition chamber disposed in the order of manufacturing steps, in which a phosphorus-type thin film is grown in the first vapor deposition chamber and a crystal of a nitrogen-type thin film is grown in the second vapor deposition chamber, resulting in the formation of a laminated thin film layer with the nitrogen-type thin film layer section laminated on the phosphorus-type thin film layer section (i.e., a compound semiconductor). Therefore, in this case, the present invention can improve a quality of each thin film layer to a remarkable extent while suppressing the formation of oxides at an interface between the thin film layers.

According to the invention as described in claim 6, the first vapor deposition chamber is supplied with a phosphine as a phosphorus-type raw material for growing a crystal of the phosphorus-type thin film layer and the second vapor deposition chamber is supplied with a hydrazine raw material or ammonia gas as a nitrogen-type raw material for growing a crystal of the nitrogen-type thin film layer. The supply of such a raw material into each of the vapor deposition chambers can form a laminated thin film layer with the nitrogen-type thin film layer laminated on the phosphorus-type thin film layer (i.e., a compound semiconductor). This invention can specifically realize the action and effects as the invention as described in claim 5 can do.

Moreover, upon manufacturing the compound semiconductor, the supply of the first vapor deposition chamber with the phosphine as a phosphorus-type raw material to grow a crystal of the phosphorus-type thin film layer and the supply of the second vapor deposition chamber with the hydrazine or ammonia gas as the nitrogen-type raw material to grow a crystal of the nitrogen-type thin film layer can prevent an exposure (i.e., a reaction) of the phosphine and/or those derived therefrom (i.e., those stuck to the chamber, precipitates, etc.) to the hydrazine-type raw material or ammonia gas, thereby making sure to prevent irregular burning (e.g., explosion) that is likely to occur upon exposure.

According to the invention as described in claim 7, the thin film layer of boron phosphide as a crystal of a phosphide compound and the thin film layer of potassium nitride as a crystal of a nitride compound are formed, thereby making sure to form a compound semiconductor composed of the potassium nitride thin film layer integrated with the crystal substrate through the phosphorus-type thin film layer as a buffer layer, even if a lattice constant of the potassium nitride thin film layer as the outermost layer would largely differ from that of the crystal substrate. The invention as described in claim 7 can specifically realize the action and effects similar to those achieved by the invention as described in claim 5 in terms of the manufacturing of the thin film layer.

According to the invention as described in claim 8, the outermost layer of the thin film layer is inspected for its crystal conditions during the conveyance of the crystal substrate from one vapor deposition chamber to the adjacent vapor deposition chamber to determine on the results of inspection as to whether or not to continue the manufacturing of the thin film layer. If the crystal conditions of the outermost thin film layer would have been found inadequate to let the manufacturing of thin film layer go further, then the manufacturing of thin film layer can be suspended immediately, thereby preventing useless manufacturing operations and an occurrence of poor-quality products.

The invention as described in claim 9 provides a compound semiconductor that can be manufactured easily while decreasing costs due to the use of a silicon substrate readily available and having favorable properties in terms of electrode arrangements and so on.

According to the invention as described in claim 10, the quality of each thin film layer constituting the laminated layer structure can be improved to a remarkable extent because the subsequently laminated layer causes no decrease in its quality due to the fact that a crystal of each thin film layer is grown on the crystal substrate one on another in the exclusive vapor deposition chamber corresponding to the respective thin film layer and, therefore, no unthinkable reaction is caused to occur in the step of forming the subsequently laminated layer after the formation of the previous thin film layer.

Moreover, the discrete ventilation system is used for ventilating each of the exclusive vapor deposition chambers so that irregular burning (e.g., explosion) can be prevented in each of the discrete ventilation systems, which may be caused to occur due to an exposure (i.e., a reaction) of the raw materials and/or those derived therefrom to each other.

According the invention as described in claim 11, the apparatus for the manufacturing of the compound semiconductor is provided with a plurality of the vapor deposition chambers each for growing a crystal of each thin film layer individually on the crystal substrate so that a crystal of each thin film layer can be grown one on another on the crystal substrate in the vapor deposition chamber exclusive for each thin film layer. Further, the vapor deposition chambers are connected to each other through the conveyor chamber while ensuring a conveyor space for conveying the crystal substrate. The conveyor chamber is disposed so as to become in an oxidation controlling atmosphere at least during the conveyance of the crystal substrate, thereby allowing the conveyor space for the crystal substrate to be in the oxidation controlling atmosphere suppressing the oxidation of the thin film layer. Therefore, the invention as described in claim 11 provides an apparatus for the manufacturing of the compound semiconductor for carrying out the method for the manufacturing of the compound semiconductor according to the method as described in claim 1.

According to the invention as described in claim 13, each of the vapor deposition chambers is disposed next to the loadlock chamber and the conveyor chamber is disposed as an inner space of a glove box. As the glove box is so disposed as to enclose the loadlock chamber of each vapor deposition chamber, the apparatus for the manufacturing of the compound semiconductor according to the invention can be composed specifically and precisely using a plurality of conventional vapor deposition device (i.e., provided with a vapor deposition chamber and a loadlock chamber disposed next thereto) and the glove box.

The invention as described in claim 14 provides an apparatus for the manufacturing of the compound semiconductor for carrying out the method for manufacturing the compound semiconductor as described in claim 5, wherein the plural vapor deposition chambers are composed of a first vapor deposition chamber and a second vapor deposition chamber for growing a crystal in the step following the crystal growth step in the first vapor deposition chamber. In this method, the first vapor deposition chamber is provided in order to grow a crystal of the phosphorus-type thin film layer and the second vapor deposition chamber is provided in order to grow a crystal of the nitrogen-type thin film layer. This arrangement of the vapor deposition chambers allows growing the crystal of each of the phosphorus-type and the nitrogen-type thin film layers one over another on the crystal substrate in the exclusive vapor deposition chamber corresponding to the respective thin film layers.

Given the phosphorus-type thin film layer being a thin film layer of boron phosphide as a crystal of a phosphide compound and the nitrogen-type thin film layer being a thin film layer of gallium nitride as a crystal of a nitride compound, the invention as described in claim 15 provides the first vapor deposition chamber exclusive for growing a crystal of the boron phosphide thin film layer and the second vapor deposition chamber exclusive for growing a crystal of the gallium nitride thin film layer. Therefore, the invention as described in claim 15 specifically provides an apparatus for the manufacturing of the compound semiconductor for carrying out the method as described in claim 7.

The invention as described in claim 16 can provide an apparatus for the manufacturing of the compound semiconductor for carrying out the manufacturing method as described in claim 8, in which the crystal substrate is composed of a silicon substrate.

### BRIEF DESCRIPTION OF DRAWINGS

FIG. 1 is a plane view schematically showing the manufacturing apparatus according to the first embodiment of the present invention.

FIG. 2 is a side view schematically showing the manufacturing apparatus according to the first embodiment of the present invention.

FIG. 3 is an illustration of manufacturing steps to be applied by the manufacturing apparatus according to the first embodiment of the present invention.

FIG. 4 is a plane view schematically showing the manufacturing apparatus according to the second embodiment of the present invention.

FIG. 5 is a side view schematically showing the manufacturing apparatus according to the second embodiment of the present invention.

### BEST MODES FOR CARRYING OUT THE INVENTION

The present invention will be described by way of specific embodiments with reference to the accompanying drawings.

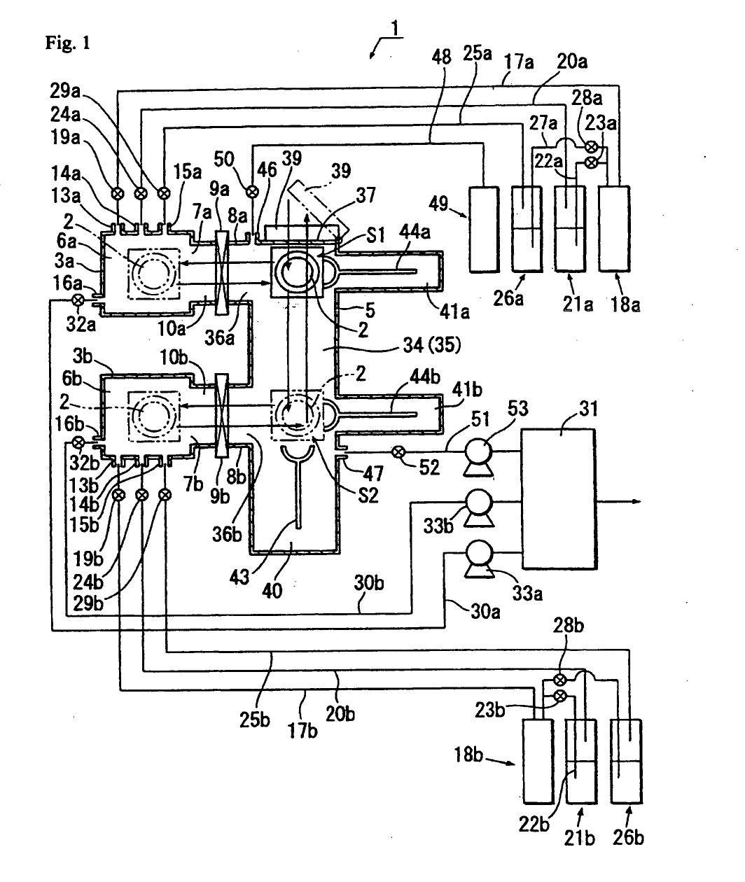

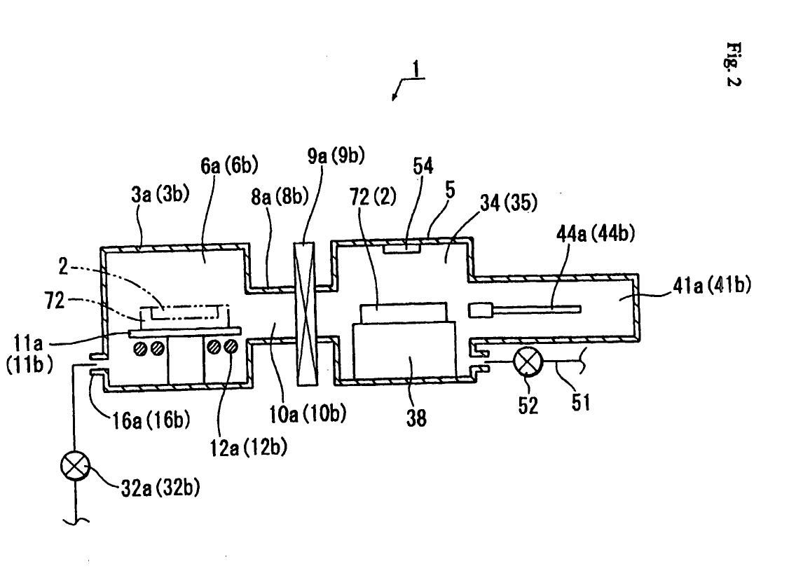

FIGS. 1 and 2 show each an apparatus 1 for the manufacturing of a compound semiconductor according to the first embodiment of the present invention. The manufacturing apparatus 1 consists of a first vapor deposition section 3a and a second vapor deposition section 3b each for growing a crystal of a thin film layer on a silicon substrate 2 as a crystal substrate (disposed over a tray), and a conveyor section 5 connecting the first vapor deposition section 3a to the second vapor deposition section 3b.

The first vapor deposition section 3a is provided in its inside with a first vapor deposition chamber 6a which has an opening 7a for conveying a substrate in and out the chamber, and the opening 7a is connected at its one end to a conveyor section 8a which is in turn provided with a gate valve 9a. The conveyor section 8a has a conveyor pathway 10a in communication with the first vapor deposition chamber 6a in order to allow the silicon substrate 2 to be conveyed therefrom or in thereinto. The conveying pathway 10a is opened or closed with the gate valve 9a. As shown in FIG. 2, the first vapor deposition chamber 6a is provided with a support table 11a, a heater 12a for heating the silicon substrate 2 disposed on the support table 11a, and a cooling device (not shown).

The first vapor deposition chamber 6a has a carrier gas inlet 13a for introducing a carrier gas, a first raw gas inlet 14a and a second raw gas inlet 15a, respectively, for growing a crystal of each thin film layer, and a gas outlet 16a for discharging gas within the first vapor deposition chamber.

The carrier gas inlet 13a is connected through a carrier gas line (pipe) 17a to a carrier gas source 18a which is filled with the carrier gas. As the carrier gases, there may be used hydrogen gas H₂ in this embodiment of the present invention. The carrier gas line 17a is provided with a flow control valve 19a, and the carrier gas is supplied to the carrier gas inlet 13a via the carrier gas line 17a while adjusting a flow of the carrier gas with the flow control valve 19a.

The first raw gas inlet 14a is connected through a first raw gas line (pipe) 20a to a first raw material source 21a in which the first raw material is stored in the form of a liquid. The carrier gas is introduced into the first raw material from the carrier gas source 18a through a carrier gas supply tube 22a. The first raw material is gasified by supplying the carrier gas (i.e., bubbling therewith), and the resulting first raw gas is led to the first raw gas line 20a. The carrier gas supply tube 22a is provided with a flow control valve 23a which adjusts a flow of the carrier gas and in turn adjusts the gasification of the first raw material. As the first raw materials to be used in this embodiment of the present invention, there may advantageously be used, for example, tributylboron (TEB). The first raw gas line 20a is provided with a flow control valve 24a which adjusts a flow of the first raw gas to supply to the first raw gas inlet 14a through the first raw gas line 20a.

The second raw gas inlet 15a is connected through a second raw gas line (pipe) 25a to a second raw material source 26a in which the second raw material is stored in the form of a liquid. Into the second raw material, there is introduced the carrier gas from the carrier gas source 18a through a carrier gas supply tube 27a. The introduction (i.e., bubbling) of the carrier gas into the second raw material allows a gasification of the second raw material, and the resulting gasified second raw material is supplied to the second raw gas line 25a. The carrier gas supply tube 27a is provided with a flow control valve 28a which adjusts a flow of the carrier gas to adjust the gasification of the second raw material. As the second raw gas to be used in this embodiment, there may be used, for example, tert.-butylphosphine (TBP) as a phosphorus-type raw material. The second raw gas line 25a is provided with a flow control valve 29a which adjusts a flow of the second raw gas to lead to the second raw gas inlet 15a through the second raw gas line 25a.

To the gas outlet 16a is connected a gas abatement device 31 through a ventilation line (pipe) 30a as a ventilation system. The ventilation line 30a is provided with a shut-off valve 32a on the upstream side and a vacuum pump 33a on the downstream side. By opening the shut-off valve 32a, the first vapor deposition chamber 6a can be made in a state of vacuum or in an approximate state by the vacuum pump 33a. Then, the gas in the first vapor deposition chamber 6a is discharged to the gas abatement device 31 through the ventilation line 30a.

The second vapor deposition section 3b and the structuring matters relating thereto are basically equal to the first vapor deposition section 3a and the structuring matters relating thereto. Therefore, the same description regarding the first vapor deposition section 3a and the structuring matters relating thereto are applicable in substantially the same manner to the second vapor deposition section 3b and the structuring matters. A description of substantially the same elements relating to the second vapor deposition sections 3a and the relating matters as the first vapor deposition section 3b, etc., is omitted by substituting the suffix “a” of the reference numeral of the first vapor deposition section 3a for the suffix “b”, with the exception of features and characteristics of the second vapor deposition section 3a.

The second vapor deposition section 3b is juxtaposed with the first vapor deposition section 3a in a given spaced relationship in such a state that an opening 7b for conveying the substrate in and out the chamber is disposed opposite to the opening 7a of the first vapor deposition section 3a. As the raw gas source to be fed to the second vapor deposition chamber 6b of the second vapor deposition section 3b, there may be disposed a third raw material source 21b corresponding to the first raw material source 21a, a fourth raw material source 26b corresponding to the second raw material source 26a, and a carrier gas source 18b corresponding to the carrier gas source 18a. In this embodiments of the present invention, there may be used, for example, a third raw material, such as ammonia water, etc. as a nitrogen-type raw material for the third raw material source 21b, a fourth raw material such as trimethylgallium (TMG), etc. for the fourth raw material source 26b, and a carrier gas for the carrier gas source 18b, such as hydrogen gas H₂, as used for the carrier gas source 18a.

As the nitrogen-type raw materials for the third raw material, there may also be used a hydrazine-type raw material such as monomethylhydrazine, dimethylhydrazine, etc., in addition to ammonia water and so on as described above.

The conveyor section 5 is disposed extending in the direction in which the first vapor deposition section 3a is juxtaposed with the second vapor deposition section 3b and parallel to the first and second vapor deposition sections 3a and 3b. The conveyor section 5 is provided therein with a conveyor chamber 34, and the conveyor chamber 34 is in turn provided with a conveyor space having a shape along the shape of the conveyor section 5 and extending in the direction of elongation of the conveyor section 5. The conveyor chamber 34 is in turn provided with openings such as substrate conveying openings 36a and 36b, disposed with the openings 7a and 7b of the first and second vapor deposition chambers 6a and 6b, respectively. To the substrate conveying opening 36a (36b) of the conveyor chamber 34 is connected the other end portion of the conveyor section 8a (8b). The conveyor chamber 34 is connected to the first and second vapor deposition chambers 6a and 6b by the conveyor pathways 10a and 10b, respectively.

The conveyor chamber 34 has a substrate-conveying opening 37 at one end in the elongation direction in order to convey a substrate thereinto or therefrom and is provided inside (in the conveyor space 35) with a table 38 (see FIG. 2). The substrate-conveying opening 37 is opened and closed with a shut-off door 39 to convey the silicon substrate 2 as a crystal substrate into the conveyor chamber 34 from the outside and from the outside to the outside. The table 38 is disposed extending astride the substrate-conveying openings 36a and 36b of the conveyor chamber 34 in this embodiment, and the silicon substrate conveyed into the conveyor chamber 34 from the substrate-conveying opening 37 is placed on the table 38 in a region where the first and second vapor deposition chambers 6a and 6b are juxtaposed opposite to each other. In the description which follows, the position in the region opposite to the first vapor deposition chamber 6a at which the silicon substrate 2 is disposed on the table 38 is referred to as a first position S1 and the position in the region opposite to the second vapor deposition chamber 6b at which the silicon substrate 2 is disposed on the table 38 is referred to as a second position S2.

The conveyor chamber 34 has spaces 40, 41a and 41b, respectively, in which conveying tools are accommodated. The accommodation space 40 is disposed extending outwards from the second vapor deposition section 3b in the direction of juxtaposition of the first and second vapor deposition sections 3a and 3b in order to accommodate a conveyor fork 43 which grasps a susceptor 72 with the silicon substrate 2 loaded thereon and conveys the susceptor 72 in the direction of elongation of the conveyor section 5. The conveyor fork 43 conveys the silicon substrate 2 from the first position S1 to the second position S2. The accommodation space 41a is disposed extending outwards from the conveyor space 35 in the direction of juxtaposition of the first vapor deposition chamber 6a and the conveyor chamber 34 (i.e., in the right- and left-hand direction in FIG. 1) and at the position opposite to the first vapor deposition section 6a. The accommodation space 41a is also accommodated with a conveyor fork 44a in substantially the same manner as the conveyor fork 43, and the conveyor fork 44a conveys the silicon substrate 2 between the first vapor deposition chamber 6a and the conveyor chamber 34. The accommodation space 41b is formed extending outwards from the conveying space 35 in the direction of juxtaposition of the second vapor deposition chamber 6b and the conveyor space 34 (i.e., in the right- and left-hand direction in FIG. 1) and disposed opposite to the second vapor deposition chamber 6b. The accommodation space 41b is also accommodated with a conveyor fork 44b in a way similar to the conveyor forks 43 and 44a, and the silicon substrate 2 is conveyed by the conveyor fork 44b between the second vapor deposition chamber 6b and the conveyor chamber 34. As described above, the silicon substrate 2 is conveyed in substantially the same way by the conveyor forks 44a and 44b through the susceptor 72, and a description of the conveyance of the silicon substrate 2 through the susceptor 72 is omitted from the description that follows below.

The conveyor chamber 34 is provided with an inert gas inlet 46 for introducing an inert gas and a gas outlet 47 for discharging the gas in the conveyor chamber 34. The inert gas inlet 46 is connected to an inert gas source 49 through an inert gas line (pipe) 48 which is in turn stored with an inert gas, such as nitrogen N₂ gas in this embodiment. The inert gas line 48 is provided with a flow control valve 50 for adjusting a flow of the inert gas to be introduced in the conveyor chamber. After adjustment of the flow of the inert gas with the flow control valve 50, the inert gas is fed to the inert gas inlet 46 through the inert gas line 48. The ventilation line 51 is provided with a shut-off valve 52 on the upstream side and a vacuum pump 53 on the downstream side, and the conveyor chamber 34 is made in a state of vacuum or in an approximate state by the action of the vacuum pump 53 while opening the shut-off valve 52. Further, the gas present in the conveyor chamber 34 is discharged through the ventilation line 51 to the gas abatement device 31.

The conveyor chamber 34 is provided with an inspection device 54 at its upper inner wall as shown in FIG. 2. The inspection device 54 is located over the second position S2 to inspect conditions of a crystal (i.e., a crystal surface condition, an oxidation condition, etc.) of the first thin film layer on the silicon substrate 2 disposed over the second position S2 and outputs a result of inspection of the crystal conditions. The inspection device 54 also determines on the basis of the result of inspection as to whether the further process for the manufacturing of the compound semiconductors is to be continued or not. In the case where the apparatus for the manufacturing of the compound semiconductor is automated, the content (i.e., continuation or suspension of the manufacturing process) of operations of the conveyor forks 43 and 45 is determined on the basis of output signals of the inspection device. As the inspection device to be used for the present invention, there may be used a photoluminescence device for example.

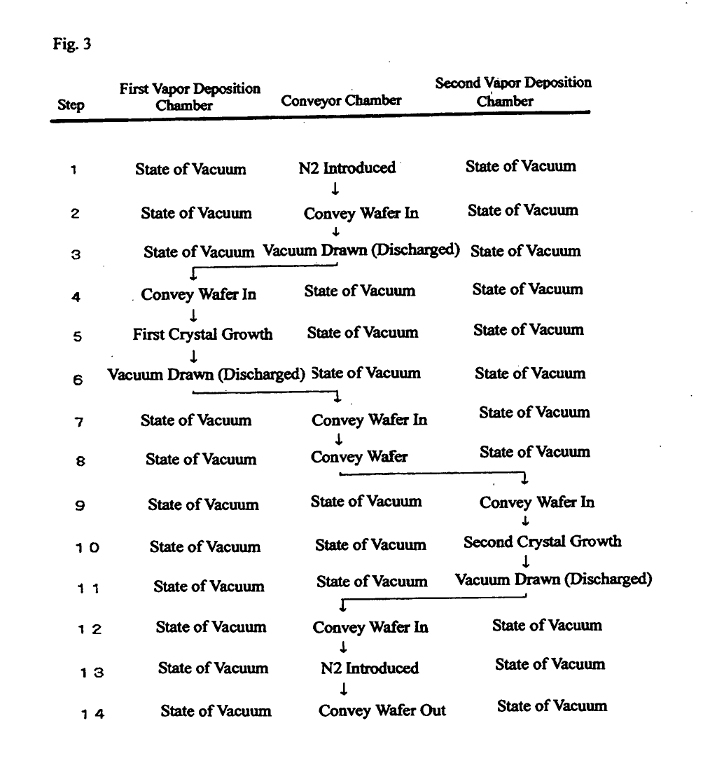

Then, a description is made regarding the method for the manufacturing of the compound semiconductor according to the first embodiment of the present invention as well as the operations of the manufacturing apparatus 1 with reference to FIGS. 1 and 3. In FIGS. 1 and 3, the arrow symbol indicates a state of conveying the silicon substrate 2 in the manufacturing apparatus 1.

A description will first be made regarding the state in which the first and second vapor deposition chambers 6a and 6b are each in a state vacuum and the conveyor chamber 34 is in a state in which it is filled with nitrogen gas N₂. This state is the one in which the compound semiconductor has been removed from the conveyor chamber 34 after the previous manufacturing of the compound semiconductor has been finished. In order to manufacture a new compound semiconductor from the state as described above, the conveyor chamber 34 is fed with nitrogen (N₂) gas as an inert gas to make the conveyor chamber 34 in a state in which it is filled with nitrogen gas (step 1). The state in which the nitrogen gas is introduced is set by making the pressure inside somewhat higher than the atmospheric pressure, and this state allows no penetration of air into the apparatus from the outside even if the shut-off door 39 would be opened.

As the conveyor chamber 34 has been filled with nitrogen (N₂) gas, the shut-off door 39 of the conveyor chamber 34 is opened and a fresh silicon substrate 2 as a wafer is then introduced into the conveyor chamber 34 and set at the first position S1 inside the conveyor chamber 34 (step 2). The silicon substrate in this stage is in a fresh state in which no thin film layer is yet formed. The introduction of the silicon substrate 2 to the first position S1 may be done by mechanical or manual operations.

As the silicon substrate 2 has been introduced into the conveyor chamber 34 and set at the predetermined position, the shut-off door 39 of the conveyor chamber 34 is closed and vacuum is drawn from the conveyor chamber 34 to a state of vacuum by completely discharging the nitrogen gas from the conveyor chamber 34 (step 3). As the pressure in the conveyor chamber 34 becomes equal to the vacuum state of the first vapor deposition chamber 6a, the gate valve 9a is opened to convey the silicon substrate 2 into the first vapor deposition chamber 6a with the conveyor fork 44a and set at the predetermined position (step 4).

As the silicon substrate 2 has been introduced into the first vapor deposition chamber 6a and set, the gate valve 9a is closed and a process of growing a crystal (i.e., a first crystal growth) is carried out in the first vapor deposition chamber 6a (step 5). More specifically, the conditions inside the first vapor deposition chamber 6a is adjusted by introducing a carrier gas (H₂) into the first vapor deposition chamber 6a and adjusting a temperature of the silicon substrate 2, the first raw gas (TEB) and the second raw gas (TBP) are introduced into the first vapor deposition chamber 6a while discharging the gas from the first vapor deposition chamber 6a with the vacuum pump 33a. This allows the formation of a boron phosphide thin film layer as the first thin film layer on the silicon substrate 2 and this crystal growth step is continued until the boron phosphide thin film layer reaches a predetermined film thickness. It is to be further noted herein that, although the shut-off valve 32a is opened and the operation of the vacuum pump 33a is continued during the crystal growth step, the pressure in the first vapor deposition chamber 6a becomes reduced or ambient (for example, 0.1 to 760 Torr) due to introduction of various gases into the first vapor deposition chamber 6a.

When the crystal growth step in the first vapor deposition chamber 6a has been finished in the predetermined manner, the supply of the carrier gas, the first and second raw gases into the first vapor deposition chamber 6a was suspended, and vacuum was drawn from the first vapor deposition chamber 6a (step 6). This allows the residual gas and the remaining materials, such as stuck materials, precipitates, etc., to be discharged into the gas abatement device 31 and the first vapor deposition chamber 6a is made in a state of vacuum.

As the pressure in the first vapor deposition chamber 6a reached a state of vacuum in the conveyor chamber 34, the shut-off valve 32a is closed, and the gate valve 9a is opened to convey the silicon substrate 2 having the first thin film layer (i.e., the boron phosphide thin film layer) with the conveyor fork 44a to its set position S1 in the conveyor chamber 34 (step 7), followed by closing the gate valve 9a. In this case, the condition (degree) of a vacuum in the conveyor chamber 34 is advantageously set from the point of view of suppressing the formation of oxides (i.e., oxides BxOy formed by a reaction of boron with oxygen) to be caused by oxidation of the first thin film layer (i.e., the boron phosphide thin film layer) on the silicon substrate 2. As described above, this allows the formation of the oxides to be suppressed in a manner as described hereinafter, and a GaN crystal can be grown on the boron phosphide (BP) thin film layer (as the first thin film layer).

The silicon substrate 2 with the first thin film layer formed thereon is then conveyed to the second position S2 through the conveyor space 35 with the conveyor fork 43 (step 8). In this step, the silicon substrate 2 is conveyed through the conveyor space 35 in a state of vacuum, so that the first thin film layer is not oxidized to form any oxides at this stage.

As the silicon substrate 2 is conveyed to the second position S2, the conditions of the crystal of the first thin film layer are inspected with the inspection device 54. If the first thin film layer is not judged to meet with predetermined crystal standards as a result of inspection, the manufacturing step is immediately suspended. On the other hand, when the first thin film layer is judged to meet with predetermined crystal standards, the operations for manufacturing the compound semiconductor are continued. In the event where the manufacturing operations are to be continued, the gate valve 9b is opened because the vacuum state within the conveyor chamber 34 is equal to the vacuum state within the second vapor deposition chamber 6b, and the silicon substrate 2 at the second position S2 is conveyed into the second vapor deposition chamber 6b with the conveyor fork 44b (step 9)

Upon conveying the silicon substrate 2 into the second vapor deposition chamber 6b and setting it at the predetermined position, the gate valve 9b is closed to grow a crystal (i.e., a second crystal growth) in the second vapor deposition chamber 6b (step 10). More specifically, the conditions within the second vapor deposition chamber 6b are adjusted by introducing a carrier gas (H₂) and adjusting a temperature of the silicon substrate 2, a third raw gas (e.g., ammonia gas) and a fourth raw gas (e.g., TMG) are introduced into the second vapor deposition chamber 6b while discharging the gases with the vacuum pump 33b from the second vapor deposition chamber 6b. This allows the formation of a gallium nitride (GaN) thin film layer as a second thin film layer on the first thin film layer formed on the silicon substrate 2. The crystal growth step is continued until the GaN thin film layer reaches its predetermined film thickness. It is to be noted herein that, in this crystal growth step, too, the vacuum pump 33b is operated while the shut-off valve 32b is opened; however, the pressure within the second vapor deposition chamber 6b is stayed at reduced or ambient pressure (e.g., 0.1 to 760 Torr) because various gases are introduced into the second vapor deposition chamber 6b.

This can solve the problem that the GaN thin film layer cannot be laminated directly on the silicon substrate 2 due to a great difference between their lattice constants by forming the boron phosphide thin film layer as the first thin film layer on the silicon substrate 2 and utilizing it as a buffer layer, resulting the formation of a compound semiconductor with the GaN thin film layer laminated on the silicon substrate 2 through the boron phosphide thin film layer.

In this case, the first thin film layer and the second thin film layer are formed by growing crystals of the corresponding raw gas materials in the first and second vapor deposition chambers 6a and 6b, respectively, for exclusive use therefor, thereby preventing a contamination of any foreign material in the first and second thin film layers and consequently forming a compound semiconductor having a high quality. Moreover, in this embodiment, the boron phosphide thin film layer as the first thin film layer and the GaN thin film layer as the second thin film layer are formed, so that, under a normal situation, there is the possibility that the raw gases or those derived therefrom (e.g., stuck materials, precipitates, etc.) to be used for the formation of both of the thin film layers may react with each other causing an irregular burning (e.g., explosion). As described above, however, in this embodiment of the present invention, such an irregular burning such as explosion, etc. can be prevented because the first thin film layer is arranged to be formed exclusively in the first vapor deposition chamber 6a while the second thin film layer is arranged to be formed exclusively in the second vapor deposition chamber 6b discrete and independent from the first vapor deposition chamber 6a. Moreover, in this embodiment, the ventilation lines 30a and 30b for the respective vapor deposition chambers are also disposed discretely from each other in order to prevent an occurrence of such an irregular burning for sure in the ventilation system.

As the crystal growth step in the second vapor deposition chamber 6b has been finished, the introduction of the carrier gas, the third raw gas and the fourth raw gas into the second vapor deposition chamber 6b is suspended, followed by drawing vacuum from the second vapor deposition chamber 6b (step 11). This discharges the remaining materials, such as residue gases, stuck materials, precipitates, etc. into the gas abatement device 31 while making the inside of the second vapor deposition chamber 6b in a state of vacuum.

Once the state of pressure within the second vapor deposition chamber 6b becomes equal to the state of vacuum within the conveyor chamber 34, then the shut-off valve 32b is closed and the gate valve 9b is opened to convey the silicon substrate 2 with the first thin film layer (the boron phosphide thin film layer) and the second thin film layer (GaN thin film layer) formed on the silicon substrate 2 back to the second position S2 of the conveyor chamber 34 with the conveyor fork 44b (step 12).

As the silicon substrate 2 is returned to the second position S2 in the conveyor chamber 34, the gate valve 9b is closed to start with the introduction of N₂ gas into the conveyor chamber 34, thereby filling the conveyor chamber 34 with N₂ gas and elevating the pressure therein to a pressure a little bit higher than the ambient atmosphere (step 13).

When the conveyor chamber 34 is filled fully with the N₂ gas, the shut-off door 39 is opened to withdraw the resulting product with the first and second thin film layers laminated thereon (i.e., a compound semiconductor) outside with the conveyor fork 43 (step 14). At this time, even if the shut-off door 39 is opened, no air comes into the conveyor chamber 34 from the outside because the conveyor chamber 34 is set to be in a gas-filled state having a pressure somewhat higher than the atmospheric pressure.

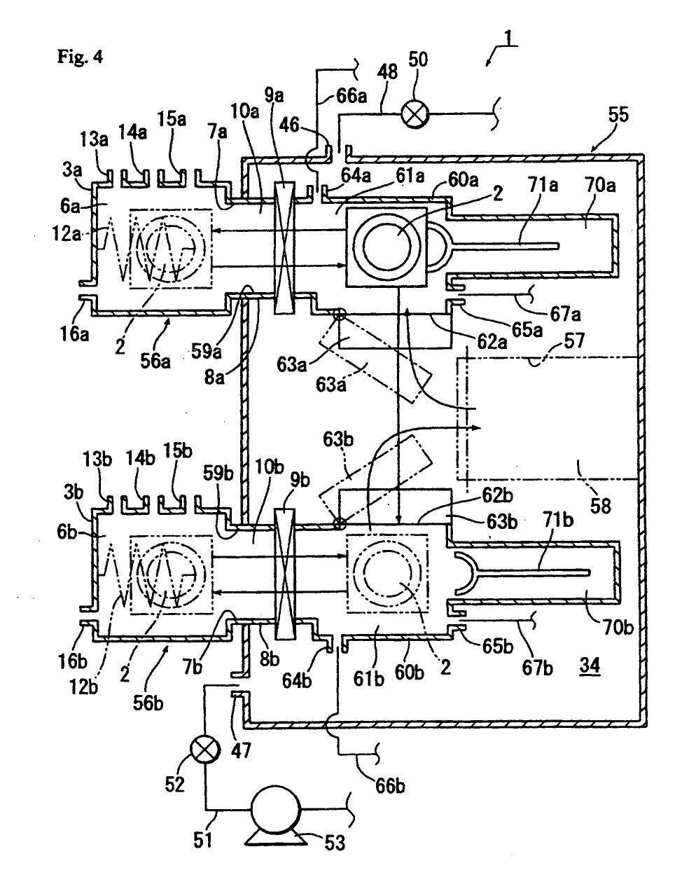

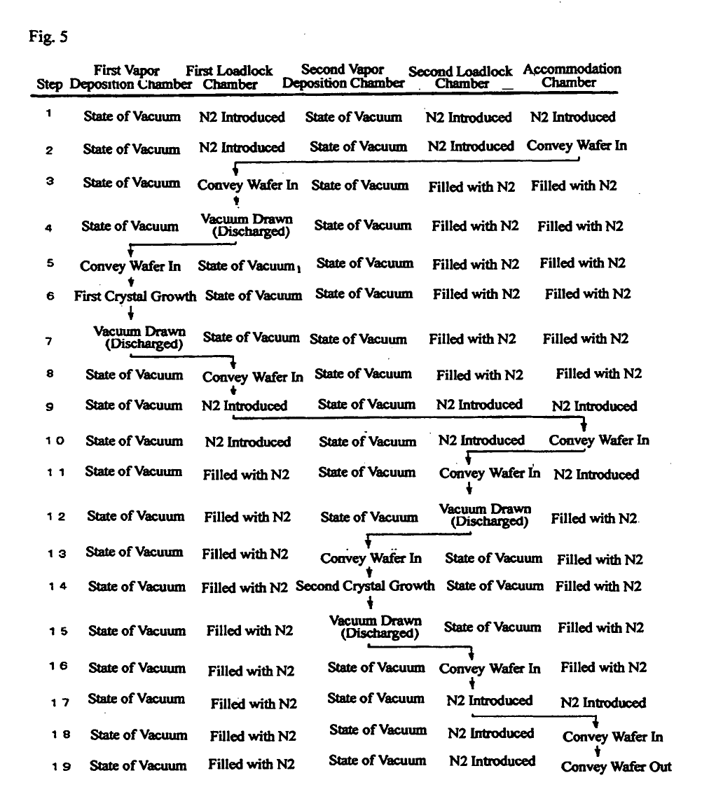

FIGS. 4 and 5 show each the second embodiment of the present invention, in which the identical structuring elements of the second embodiment are provided with the same reference numerals as those of the first embodiment. A description of the identical elements of the second embodiment will be omitted in the following description for brevity of explanation.

In the second embodiment of the present invention as shown in FIG. 4, the manufacturing apparatus 1 for manufacturing a compound semiconductor comprises a glove box 55 and two conventional vapor deposition devices, i.e., first and second metal organic chemical vapor deposition devices 56a and 56b.

The glove box 55 is provided in its inside with an accommodation chamber acting as a conveyor chamber 34 (as provided with the same reference numeral “34” as the conveyor chamber 34 in the first embodiment), and the accommodation chamber 34 has an opening 57 through which the silicon substrate 2 is conveyed thereinto or therefrom and which is opened and closed with a shut-off lid 58. The silicon substrate 2 is conveyed into the conveyor chamber 34 by opening the shut-off lid 58. The glove box 55 is further provided with conventional operating gloves (not shown) with which an operator can operate the glove box from the outside.

The glove box 55 has an inert gas inlet 46 for introducing an inert gas and a gas outlet 47 for discharging the gas within the accommodation chamber 34. To the inert gas inlet 46 is connected an inert gas source (although not shown) through an inert gas line (pipe) 48 which is in turn provided with a flow control valve 50 to adjust a flow of the inert gas. As the inert gas, there may be used, for example, nitrogen (N₂) gas, in the second embodiment of the present invention. To the gas outlet 47 is connected the gas abatement device 31 (although not shown) through a ventilation line (pipe) 51 which is in turn provided with a shut-off valve 52 on the upstream side and a vacuum pump 53 on the downstream side. The accommodation chamber 34 of the glove box 55 is made in a state of vacuum or in an approximate state by the vacuum pump 53 while opening the shut-off valve 52, and discharging the gas within the accommodation chamber 34 toward the gas abatement device 31 through the ventilation line 51. The glove box 55 also has two inlets 59a and 59b disposed in a predetermined spaced relationship, and the inlets 59a and 59b are disposed in communication with the outside and the accommodation chamber 34 of the glove box 55.

The first metal organic chemical vapor deposition device 56a has basically the same structure as the second metal organic chemical vapor deposition device 56b, and the first and second metal organic chemical vapor deposition devices 56a and 56b are mounted on the glove box 55 in substantially the same manner. Therefore, like in the first embodiment of the present invention, the first metal organic chemical vapor deposition device and the structuring elements in the second embodiment are referred to as reference numerals provided with a suffix “b” instead of the suffix “a” of the identical reference numerals for the second metal organic chemical vapor deposition device and the structuring elements in the second embodiment. Further, a description of the first metal organic chemical vapor deposition device and the structuring elements thereof is likewise applicable to the second metal organic chemical vapor deposition device and the structuring elements thereof. The description of the first metal organic chemical vapor deposition device and the structuring elements thereof can be applied to the second metal organic chemical vapor deposition device and the structuring elements thereof with the exception of features and characteristics of the second metal organic chemical vapor deposition device, etc.

In the first metal organic chemical vapor deposition device 56a, a first vapor deposition section 3a and a first loadlock section 60a are connected to each other in series through a conveyor section 8a. The conveyor section 8a and the first loadlock section 60a are inserted in the accommodation chamber 34 of the glove box 55 through the inlet 59a while ensuring air tightness with respect to the inlet 59a. These arrangements can also be applied to the second metal organic chemical vapor deposition device 56b. In the accommodation chamber 34 of the glove box 55, the conveyor section 8a and the first loadlock section 60a of the first metal organic chemical vapor deposition device 56a are disposed in a spaced relationship with the conveyor section 8b and the second loadlock section 60b of the second metal organic chemical vapor deposition device 56b.

The first loadlock section 60a has a first loadlock chamber 61a therein in order for the first vapor deposition chamber 6a not to be exposed to the atmosphere. The first loadlock chamber 61a is in turn disposed with a substrate-conveying opening 62a in communication with a second loadlock chamber 61b of the second metal organic chemical vapor deposition device 56b. In the first loadlock chamber 61a, there is disposed a table (although not shown) for supporting the silicon substrate 2. The substrate-conveying opening 62a is opened with the shut-off door 63a to communicate with the outside of the first loadlock chamber 61a, thereby conveying the silicon substrate 2. On the other hand, a substrate-conveying opening 63b of the second loadlock chamber 61b of the second metal organic chemical vapor deposition device 56b is opened toward the first loadlock chamber 61a, and the substrate-conveying opening 63b is opened and closed with the shut-off door 63b. The shut-off doors 63a and 63b of the first and second loadlock chambers 61a and 61b, respectively, are disposed to cause no interference with each other in opening and closing the door.

The first loadlock chamber 61a is provided with an accommodation chamber 70a for accommodating a conveying tool, which is formed extending outwards from the first loadlock chamber 61a in the direction of juxtaposition of the first vapor deposition chamber 6a and the first loadlock chamber 61a (i.e., in the left- and right-hand direction in FIG. 4). The accommodation chamber 70a is disposed in a spaced relationship opposite to the first vapor deposition chamber 6a and arranged to accommodate a conveyor fork 71a in substantially the same manner as the conveyor fork 44a in the first embodiment of the present invention. The conveyor fork 71a conveys the silicon substrate 2 loaded on the susceptor between the first vapor deposition chamber 6a and the first loadlock chamber 61a in the direction of juxtaposition of the first vapor deposition chamber 6a and the first loadlock chamber 61a.

Moreover, the first loadlock chamber 61a is provided with an inert gas inlet 64a through which to introduce nitrogen (N₂) gas as an inert gas (as used in the second embodiment of the present invention) and a gas outlet 65a. The inert gas inlet 64a is connected to the inert gas source (although not shown) through an inert gas line (pipe) 66a which is in turn provided with a flow control valve (although not shown). The inert gas source is stored with an inert gas such as nitrogen (N₂) gas in this embodiment of the present invention. The gas outlet 65a is connected to the gas abatement device 31 through a ventilation line (pipe) 67a which in turn comprises a shut-off valve on the upstream side and a vacuum pump on the downstream side, each being not shown. While the shut-off valve is being opened, the first loadlock chamber 61a is made in a state of vacuum or an approximate state by the vacuum pump, and the gas in the first loadlock chamber 61a is discharged through the gas ventilation line 67a to the gas abatement device 31.

Next, a description will be made regarding the method for manufacturing the compound semiconductor according to the second embodiment of the present invention, together with the operations of the manufacturing apparatus 1, with reference to FIGS. 4 and 5. In FIGS. 4 and 5, the arrow symbol indicates a direction of conveying the silicon substrate 2.

A description will be made regarding the manufacturing of a compound semiconductor from the state in which the first and second vapor deposition chambers 6a and 6b are each in a state of vacuum, the first loadlock chamber 61a is filled with N₂ gas as well as the second loadlock chamber 61b and the accommodation chamber 34 (i.e., the conveyor chamber 34) is introduced with N₂ gas. It can be noted herein that this state is the one in which the manufacturing of the previous compound semiconductor has been finished and the resulting compound semiconductor has been withdrawn from the manufacturing apparatus. In order to manufacture a new compound semiconductor from this state, first, the shut-off door 63b of the second loadlock chamber 61b is closed to maintain the state in which it is filled with N₂ gas. Then, the first loadlock chamber 61a and the accommodation chamber 34 are each fed with N₂ gas and filled therewith (step 1). As the pressure of the first loadlock chamber 61a and the accommodation chamber 34, which are filled with N₂ gas, is set to be equal to or somewhat higher than the atmospheric pressure, no air intrudes thereinto from the outside even if the shut-off lid 58 and the shut-off door 63a, etc. would be opened. As they are filled with N₂ gas up to a predetermined level, the shut-off lid 58 is opened to convey the silicon substrate 2 as a wafer (i.e., in a fresh state and being yet formed with no thin film layer at this stage) to the conveyor chamber 34 (step 2). Thereafter, the shut-off door 63 is opened to set the silicon substrate 2 at a predetermined position in the first loadlock chamber 61a (step 3).

Once the silicon substrate 2 has been conveyed into the first loadlock chamber 61a and set at the predetermined position, the shut-off door 63a is closed to draw vacuum from the first loadlock chamber 61a until the N₂ gas is no longer present therein and bring the first loadlock chamber into a state of vacuum in order to make the pressure in the first loadlock chamber 61a equal to a state of vacuum in the first vapor deposition chamber 6a. At this time, the introduction of N₂ gas into the accommodation chamber 34 is suspended to maintain the state of the conveyor chamber 34 in which it is thoroughly filled with the N₂ gas (step 4). Thereafter, as the pressure state (i.e., the state of vacuum) in the first loadlock chamber 61a becomes equal to the state of vacuum in the first vapor deposition chamber 6a, the gate valve 9a is opened to convey the silicon substrate 2 into the first vapor deposition chamber 6a with the conveyor fork 71a and set it at the predetermined position (step 5).

As the silicon substrate 2 is conveyed into the first vapor deposition chamber 6a and set at the predetermined position, the gate valve 9a is closed to grow a crystal (a first crystal growth) in the first vapor deposition chamber 6a (step 6). More specifically, as in the first embodiment of the present invention, when the conditions in the first vapor deposition chamber 6a are adjusted by introducing a carrier gas (H₂) into the first vapor deposition chamber 6a and adjusting a temperature of the silicon substrate 2, a first raw gas (TEB) and a second raw gas (TBP) are introduced into the first vapor deposition chamber 6a while discharging the gases from the first vapor deposition section 6a by the vacuum pump to form a boron phosphide thin film layer as a first thin film layer on the silicon substrate 2. This crystal growth step is continued until the crystal of the boron phosphide thin film layer grows to a predetermined film thickness. In this crystal growth step, too, various gases are introduced into the first vapor deposition chamber 6a while discharging the gases therefrom, so that the pressure in the first vapor deposition chamber 6a becomes reduced or ambient (e.g., 0.1 to 760 Torr).

As the crystal growth step in the first vapor deposition chamber 6a has been finished, the introduction of the carrier gas, the first raw gas and the second raw gas into the first vapor deposition chamber 6a is suspended and vacuum is drawn from the first vapor deposition chamber 6a (step 7). This allows the remaining matters, such as the residue gases, stuck materials and precipitates, etc., to be discharged from the first vapor deposition chamber 6a to the gas abatement device 31 and the first vapor deposition chamber 6a is made in a state of vacuum.

When the state of pressure (i.e., the state of vacuum) in the first vapor deposition chamber 6a becomes equal to the state of vacuum within the first loadlock chamber 61a, the ventilation is suspended and the gate valve 9a is opened to return the silicon substrate 2 with the first thin film layer (i.e., the boron phosphide thin film layer) formed thereon into the first loadlock chamber 61a with a conveyor fork 71a (step 8). Then, as the silicon substrate 2 is conveyed to the first loadlock chamber 61a, the gate valve 9a is closed.

As the silicon substrate 2 is returned to the first loadlock chamber 61a and the gate valve 9a is closed, N₂ gas as an inert gas is introduced into the first and second loadlock chambers 61a and 61b as well as the accommodation chamber 34 of the glove box 55 (step 9). As the state of pressure in each of the chambers 61a, 61b and 34 becomes equal to or somewhat higher than the atmospheric pressure and reaches the predetermined pressure by introducing N₂ gas into each of the chambers, the shut-off door 63a of the first loadlock chamber 61a is opened to allow an operator to use operating gloves to convey the silicon substrate 2 with the first thin film layer laminated thereon to the accommodation chamber 34 of the glove box 55 (step 10), followed by opening the shut-off door 63b and conveying the silicon substrate 2 to the second loadlock chamber 61b (step 11). In this case, the state in which N2 gas is introduced into the accommodation chamber 34, etc. of the glove box 55 can suppress the formation of oxides (specifically, oxides BxOy formed by a reaction of boron with oxygen) by oxidation of the first thin film layer on the silicon substrate 2.

When the silicon substrate 2 is conveyed into the second loadlock chamber 61b, the shut-off door 63b is closed and vacuum is drawn from the second loadlock chamber 61b to make the second loadlock chamber 61b in a state of vacuum (step 12). As the state of vacuum in the second loadlock chamber 61a becomes equal to the state of vacuum in the second vapor deposition chamber 6b, the gate valve 9b is opened and the silicon substrate 2 in the second loadlock chamber 61b is conveyed into the second vapor deposition chamber 6b with the conveyor fork 71b (step 13). In this case, an inspection device 54 for inspecting the state of a crystal of the first thin film layer is disposed in the second loadlock chamber 6b in order to inspect on the basis of inspection results as to whether to continue or suspend the operations for manufacturing the compound semiconductor.

As the silicon substrate 2 is conveyed into the second vapor deposition chamber 6b and set at the predetermined position, the gate valve 9b is closed and a crystal growth (a second crystal growth) is conducted in the second vapor deposition chamber 6b (step 14). More specifically, as the conditions in the second vapor deposition chamber 6b are adjusted by introducing a carrier gas (H₂) and adjusting a temperature of the silicon substrate 2 in substantially the same manner as in the first embodiment of the present invention, a third raw gas (ammonia gas) and a fourth raw gas (TMG) are introduced into the second vapor deposition chamber 6b while discharging the gases in the second vapor deposition chamber 6b. This allows a growth of a crystal of gallium nitride (GaN) thin film layer as a second thin film layer on the first thin film layer deposited on the silicon substrate 2. This crystal growth step is continued until the GaN thin film layer reaches a predetermined film thickness. It is to be noted herein that, in this crystal growth step, various gases are to be introduced into the second vapor deposition chamber 6b while discharging the gases, the pressure in the second vapor deposition chamber 6b becomes reduced or ambient (e.g., 0.1 to 760 Torr).

In the second embodiment of the present invention, too, these arrangements for the manufacturing steps can form the compound semiconductor with the GaN thin film layer laminated on the silicon substrate 2 through the boron phosphide thin film layer and further prevent a contamination of any foreign materials with the first and second thin film layers resulting in a formation of a high-quality compound semiconductor by growing a crystal using the predetermined raw gases in the first and second vapor deposition chambers 6a and 6b corresponding to the first and second thin film layers, respectively, thereby manufacturing a high-quality compound semiconductor.

It is without saying that any irregular burning phenomenon (e.g., explosion) resulting from the first, second, third and fourth raw gases can be prevented thoroughly both in each of the vapor deposition chambers 6a and 6b and the ventilation system in this embodiment of the present invention, too, because the first and second thin film layers are formed in the first and second vapor deposition chambers 6a and 6b, respectively, which are disposed discretely and independently from each other and the corresponding ventilation lines are also disposed discretely and independently from the first and second vapor deposition chambers.

Upon the completion of the crystal growth step in the second vapor deposition chamber 6b in the predetermined manner, the introduction of the carrier gas as well as the third and fourth raw gases into the second vapor deposition chamber 6b is suspended and vacuum is drawn from the second vapor deposition chamber 6b (step 15). This allows the remaining materials such as residue gases, stuck materials, precipitates, etc. to be discharged from the second vapor deposition chamber 6b and discharged to the gas abatement device 31, followed by creating a vacuum in the second vapor deposition chamber 6b.

As the state of pressure (i.e., a degree of a vacuum) in the second vapor deposition chamber 6b becomes a state of vacuum in the second loadlock chamber 61b, the drawing of vacuum is suspended and the gate valve 9b is opened to convey the silicon substrate 2 with the first and second thin film layers (i.e., the boron phosphide thin film layer and the GaN thin film layer, respectively) formed thereon back to the second loadlock chamber 61b with the conveyor fork 71b (step 16). Upon returning the silicon substrate 2 to the second loadlock chamber 61b, the gate valve 9b is closed to start with the introduction of N2 gas into the second loadlock chamber 61b and the accommodation chamber 34 of the glove box 55 (step 17).

As the state of pressure of the N₂ gas in the second loadlock chamber 61b becomes equal to the state of pressure in the accommodation chamber 34 of the glove box 55, the shut-off door 63b of the second loadlock chamber 61b is opened to allow an operator to use the operating gloves of the glove box 55 and convey the silicon substrate 2 with the first and second thin film layers laminated thereon to the accommodation chamber 34 of the glove box 55 (step 18). Thereafter, the shut-off lid 58 of the glove box 55 is opened to withdraw the silicon substrate 2 to the outside (step 19). As the pressure in the accommodation chamber 34 of the glove box 55 at this point of time is in a state in which it is filled with N₂ gas, which in turn is equal to or somewhat higher than the atmospheric pressure, the air does not penetrate into the accommodation chamber from the outside even if the shut-off lid 58 is opened.

### Example 1

A silicon substrate 2 (a wafer) having a diameter of 2 inches and a plane index of (100) was conveyed from the first loadlock chamber 61a in the state of a vacuum into the first vapor deposition chamber 6a in a state of vacuum in accordance with the procedures of the second embodiment of the present invention. After the first vapor deposition chamber 6a was shut up from the outside, hydrogen gas as a carrier gas was introduced into the first vapor deposition chamber 6a to make the chamber in an atmosphere of hydrogen and heated the silicon substrate 2 to 750° C. Then, the first vapor deposition chamber 6a was supplied with triethylboron (TEB) and tert.-butylphosphine (TBP), each gasified by the carrier gas (e.g., H, in this example), to grow a crystal of boron phosphide on the silicon substrate 2 for about 1 hour, resulting in the formation of a boron phosphide thin film layer having a film thickness of 3 micron. After the first vapor deposition chamber 6a was cooled to room temperature and vacuum was drawn in the chamber by discharging the gases, the silicon substrate 2 with the boron phosphide thin film layer formed thereon was conveyed to the first loadlock chamber 61a in which a state of vacuum is maintained. Upon returning the silicon substrate 2 to the first loadlock chamber 61a, then the introduction of N₂ gas was started in the first loadlock chamber 61a, the accommodation chamber 34 and the second loadlock chamber 61b and continued until the pressure in each of the chambers 61a, 34 and 61b reached the predetermined pressure equal to or somewhat higher than the atmospheric pressure. As the pressure in each of the first loadlock chamber 61a, the accommodation chamber 34 and the second loadlock chamber 61b reached the predetermined pressure, the first loadlock chamber 61a was opened to withdraw the silicon substrate 2 into the accommodation chamber 34 in which it was filled with N₂ gas by 90% or higher. The silicon substrate 2 was then conveyed from the accommodation chamber 34 to the second loadlock chamber 61b which was likewise stayed in a state filled with N₂ gas, and the shut-off door 63b of the second loadlock chamber 61b was closed to make the inside of the second loadlock chamber 61b in a state of vacuum. After the state of vacuum in the second loadlock chamber 61b was confirmed, the gate valve 9b was opened and the silicon substrate 2 was conveyed into the second vapor deposition section 6b. Then, the gate valve 9b was closed to shut the second vapor deposition chamber 6b out from the outside, and hydrogen gas as a carrier gas was introduced into the second vapor deposition chamber 6b, resulting in making the chamber in a hydrogen atmosphere and setting the pressure in the chamber to 500 Torr and the temperature to 1,200° C. Thereafter, trimethylgallium (TMG) as a gallium source, gasified with the carrier gas (e.g., H, in this example), and ammonia gas as a nitrogen source were introduced into the second vapor deposition chamber 6b, resulting in the growth of a crystal of GaN thin film layer (i.e., a GaN crystal of a hexagonal type) on the boron phosphide thin film layer formed on the silicon substrate 2. At this time, a dislocation was caused to occur from an interface between the GaN thin film layer and the boron phosphide thin film layer, however, a density of dislocation in the GaN thin film layer was 10⁵ crystals per cm².

### Comparative Example

As a comparative example, the glove box 55 was stayed under atmosphere instead of atmosphere of the inert gas, upon conveying the silicon substrate 2 from the first loadlock chamber 61a to the second loadlock chamber 61b. At this occasion, the dislocation was caused to occur from an interface between the GaN thin film layer and the boron phosphide thin film layer, and a density of dislocation in the GaN thin film layer was found to be 10⁸ crystals per cm². This comparative example was carried out under the same conditions as Example 1 except the atmosphere of the glove box 55 as described above.

The above results indicate that the atmosphere of the inert gas (i.e., oxidation controlling atmosphere) between the first metal organic chemical vapor deposition device 56a and the second metal organic chemical vapor deposition device 56b is effective upon the conveyance of the silicon substrate 2 from the point of view of preventing an occurrence of dislocation defects in a crystal.

### Example 2

An AlP crystal having a diameter of 2 inches and a plane index of (111), which is relatively close to a lattice constant of a silicon substrate, was grown for 30 minutes using as raw materials trimethylaluminum (TMA) and tert.-butyl phosphine (TBP) on the silicon substrate 2 in the first vapor deposition chamber 6a in accordance with the second embodiment of the present invention as described above by heating the silicon substrate 2 to 1,000° C. and making the chamber in the hydrogen atmosphere of 400 Torr. Thereafter, the first vapor deposition chamber 6a was cooled to room temperature and the silicon substrate 2 was conveyed from the first vapor deposition chamber 6a to the second vapor deposition chamber 6b through the accommodation chamber 34 (in a state filled with N₂ gas) of the glove box. In the second vapor deposition chamber 6b, a crystal was grown for 1 hour using as raw materials trimethylindium (TMIn) and ammonia gas activated partially by electric plasma under the conditions under which the temperature in the chamber was set to 550° C. and the hydrogen atmosphere to 300 Torr. As a result, an InN crystal was grown as a second thin film layer, resulting in the formation of a compound semiconductor with the InN thin film layer (as the second thin film layer) laminated on the AlP thin film layer (as the first thin film layer) formed on the silicon substrate 2. In this manufacturing steps, the silicon substrate 2 with the AlP thin film layer laminated thereon as the first thin film layer was conveyed to the second vapor deposition chamber 6b through the accommodation chamber 34 of the glove box 55 in a state filled with N₂ gas and the oxidation of the boron phosphide thin film layer is suppressed during the conveyance of the silicon substrate, thereby achieving a density of dislocation within the thin film layer at 10⁵ per cm² as comparable as the good result of Example 1.

It is to be noted that, in the event where a crystal was grown in separate vapor disposition chambers, a monocrystal could little be formed because oxygen was caused to adhere to the surface of aluminum due to a high oxygen dissolution of the aluminum, a poor affinity to an InN crystal growing at a relatively low temperature, and a great difference in lattice constants between them. However, this drawback was overcome in this example by forming a monocrystal region, although partially, by conveying the InN thin film layer through the accommodation chamber 34 of the glove box 55 under atmosphere of the inert gas (under an oxidation controlling atmosphere).

### Example 3

In accordance with the procedures of the second embodiment of the present invention, a crystal of a boron phosphide thin film layer was grown on a silicon substrate 2 having a diameter of 2 inches and a plane index of (100) in the first vapor deposition chamber 6a using as raw gas materials triethylboron (TEB) and tert.-butylphosphine (TBP) while the silicon substrate 2 was heated to a substrate temperature of 750° C. under the hydrogen atmosphere. The crystal growth was continued for about 1 hour to give a boron phosphide thin film layer having a film thickness of 3 microns. Thereafter, the first vapor deposition chamber 6a was cooled to room temperature and the resulting silicon substrate 2 was conveyed from the first vapor deposition chamber 6a to the second vapor deposition chamber 6b through the accommodation chamber 34 of the glove box 55 which was kept in a state filled with N₂ gas. The second vapor deposition chamber 6b was adjusted to a temperature of 500° C. and a hydrogen atmosphere of 500 Torr and then fed with ammonia gas as the nitrogen source and trimethylindium (TMIn) as an indium source to grow a crystal of an InN thin film layer as the second thin film layer. As a result, a compound semiconductor was obtained by laminating the InN thin film layer (as the second thin film layer) on the boron phosphide thin film layer (as the first thin film layer) formed on the silicon substrate 2. The above steps produced the thin film layer having a favorable density of dislocation of 10⁵ per cm² because the oxidation of the boron phosphide thin film layer could be suppressed during the conveyance of the silicon substrate 2 to the second vapor deposition chamber 6b through the accommodation chamber 34 of the glove box 55 in the state in which it was filled with N₂ gas.

It is to be noted herein that, as there was a difference in lattice constant by approximately 7% between boron phosphide and indium nitride crystals when they are each in the form of a cubic lattice, it was difficult to form a monocrystal. It was found, however, that a monocrystal region existed although it was at an approximately 5-mm angle only by preventing the oxidation of an interface to the greatest possible extent. Some factors can be considered as reasons for inhibiting the formation of a monocrystal; however, it is evident that an adhesion of oxygen to the phosphide compound is one of the factors. Moreover, this crystal can be expected to become a substitute for a GaAs crystal and to be applied to an electronic device, a luminescence device, and so on.

### Example 4

In accordance with the second embodiment of the present invention, a boron phosphide crystal was grown on a silicon substrate 2 having a diameter of 2 inches and a plane index of (100) using as raw gas materials triethylboron (TEB) and tert.-butylphosphine (TBP) in the first vapor deposition chamber 6a while heating the silicon substrate 2 to a temperature of 750° C. under the hydrogen atmosphere. The boron phosphide thin film layer having a film thickness of 3 microns was obtained by carrying out the crystal growth for about 1 hour. Thereafter, the first vapor deposition chamber 6a was cooled to room temperature, and the silicon substrate 2 was conveyed from the first vapor deposition chamber 6a to the second vapor deposition chamber 6b through the accommodation chamber 34 of the glove box 55 in a state filled with N₂ gas. In the second vapor deposition chamber 6b, an AlN crystal was grown using as raw gas materials ammonia gas as a nitrogen source and trimethylaluminum (TMA) as an aluminum source at a temperature of 900° C., resulting in the formation of a compound semiconductor with the AlN thin film layer (as the second thin film layer) laminated on the boron phosphide thin film layer (as the first thin film layer) formed on the silicon substrate 2. In these steps, the thin film layer having a favorable density of dislocation of 10⁵ per cm² was formed because the oxidation of the boron phosphide thin film layer could be suppressed during the conveyance of the silicon substrate 2 with the boron phosphide thin film layer laminated thereon as the first thin film layer to the second vapor deposition chamber 6b through the accommodation chamber 34 of the glove box 55 in the state in which it was filled with N₂ gas.

As it was found difficult to grow an MN crystal directly on a silicon substrate 2 having a plane index of (100) under normal conditions, a trial was conducted to form a boron phosphate crystal as an intermediate between the AlN crystal and the silicon substrate in this example. As a result, polycrystallization was caused to occur in the event where the boron phosphide crystal was being oxidized; however, an AlN crystal was found to grow in a cubic lattice on the boron phosphide crystal when the boron phosphide crystal was conveyed through the accommodation chamber 34 of the glove box 55 in the state in which it was filled with N₂ gas. As the AlN crystal is an insulating crystal so that it can be applied in the same vapor deposition chamber to a device in a high-frequency region by growing a GaN crystal as well as to an ultraviolet laser or a luminescence device.

The above embodiments are described in order to illustrate the present invention more specifically, however, it should be understood that the present invention encompasses the embodiments which follow:

(1) As a substrate of a crystal other than the silicon substrate 2, there may be used, for example, substrates of GaAs, InP, sapphire, etc.

(2) As vapor deposition sections (or an organic metal chemical vapor deposition device), there may be used, for example, two or more vapor deposition sections, in order to suppress the oxidation of an interface surface between the thin film layers.

(3) As a nitrogen-type thin film layer as a second thin film layer, there may be formed, in addition to the gallium nitride (GaN) thin film layer, for example, a thin film layer of indium nitride, aluminum nitride, InGaN, AlGaN, etc.

(4) As a second thin film layer, there may be formed, for example, a thin film layer of an arsenide.

(5) Although the manufacturing method in accordance with the above embodiments of the present invention is carried out on the basis of Metal Organic Vapor Phase Epitaxy (MOVPE) or Metal Organic Chemical Vapor Deposition (MOCVD), there may be applied, for example, a gas epitaxial growth method utilizing the chemical transport reaction using a hydride such as diboran (B₂H₆), phosphine (PH₃), etc. or a chloride such as PCl_{S}, BCl₃, etc.

It is to be understood that the objects of the present invention are not limited to those expressly described herein and encompass any modifications and equivalents as can be described as substantially preferred or advantageous.

1. A method for manufacturing a compound semiconductor with plural thin film layers laminated on a crystal substrate using a different kind of gases, comprising:
growing a crystal of each of said plural thin film layers on said crystal substrate one over another in a plurality of vapor deposition chambers; and
conveying said crystal substrate through a conveyor space from one vapor deposition chamber to another vapor deposition chamber under an oxidation-control atmosphere under which oxidation of said thin film layer is suppressed.

2. The method as claimed in claim 1, wherein said oxidation controlling atmosphere is an atmosphere that is created by an inert gas.

3. The method as claimed in claim 2, wherein said atmosphere is created by nitrogen gas.

4. The method as claimed in claim 1, wherein said oxidation controlling atmosphere is a state of vacuum.

5. The method as claimed in claim 1, wherein said vapor deposition chambers are composed of a first vapor deposition chamber and a second vapor deposition chamber, which are disposed in the order of the manufacturing steps, in which:
said first vapor deposition chamber is to grow a crystal of a phosphorus-type thin film layer; and
said second vapor deposition chamber is to grow a crystal of a nitrogen-type thin film layer.

6. The method as claimed in claim 5, comprising:
supplying a phosphine as a phosphorus-type raw material to said first vapor deposition chamber to grow a crystal of the phosphorus-type thin film layer; and
supplying a hydrazine-type raw material or ammonia gas as a nitrogen-type raw material to said second vapor deposition chamber to grow a crystal of the nitrogen-type thin film layer.

7. The method as claimed in claim 5, comprising:
forming a boron phosphorus thin film layer as a crystal of a phosphide compound for said phosphorus-type thin film layer; and
forming a gallium nitride thin film layer as a nitrogen compound for said nitrogen-type thin film layer.

8. The method as claimed in claim 1, further comprising:
inspecting a crystal state of an outermost layer of the thin film layers during a period of time during which said crystal substrate is conveyed from one vapor deposition chamber to the next vapor deposition chamber and deciding whether to continue or suspend the manufacturing of the thin film layer on the basis of a result of inspection.

9. The method as claimed in claim 1, wherein said crystal substrate is a silicon substrate.

10. A method for the manufacturing of a compound semiconductor with plural thin film layers laminated on a crystal substrate using different kinds of gases, comprising:
growing a crystal of each of said thin film layers on said crystal substrate one after another in a plurality of vapor deposition chambers corresponding to said respective thin film layers; and
using a discrete and independent ventilation system for said respective vapor deposition chambers upon ventilation of each of said vapor deposition chambers.

11. An apparatus for manufacturing a compound semiconductor with plural thin film layers laminated on a crystal substrate, comprising:
a plurality of vapor deposition chambers for growing a crystal of each of said respective thin film layers discretely and individually on the crystal substrate; and
a conveyor chamber in communication with each of said vapor deposition chambers to ensure a conveyor space for conveying said crystal substrate; in which:
said conveyor chamber is set to become in an oxidation controlling state of suppressing an oxidation of the thin film layer at least during a period of time when said crystal substrate is being conveyed.

12. The apparatus as claimed in claim 11, wherein:
said conveyor chamber is interposed between said vapor deposition chambers; and
said conveyor chamber is set to act as a loadlock chamber for each of said vapor deposition chambers.

13. The apparatus as claimed in claim 11, comprising:
a loadlock apparatus disposed adjacent to each of said vapor deposition chambers;
said conveyor chamber formed by an inner space of a glove box; and
said glove box disposed enclosing the loadlock chamber of each of said vapor deposition chambers.

14. The apparatus as claimed in claim 11, comprising:
said plurality of vapor deposition chambers composed of a first vapor deposition chamber and a second vapor deposition chamber for growing a crystal in a step after the step using the first vapor deposition chamber;
said first vapor deposition chamber for growing a crystal of a phosphorus-type thin film layer; and
said second vapor deposition chamber for growing a crystal of a nitrogen-type thin film layer.

15. The apparatus as claimed in claim 14, wherein:
said phosphorus-type thin film layer is a boron phosphide thin film layer as a crystal of a phosphide compound; and
said nitrogen-type thin film layer is a gallium nitride thin film layer as a nitrogen compound.

16. The apparatus as claimed in claim 11, wherein said crystal substrate is a silicon substrate.
